(19) United States
(12) Patent Application Publication
(10) Pub. No.: US 2025/0089524 A1
(43) Pub. Date: Mar. 13, 2025

(54) DISPLAY SCREEN, MANUFACTURING METHOD THEREOF, AND DISPLAY DEVICE

(71) Applicant: Wuhan China Star Optoelectronics Semiconductor Display Technology Co., Ltd., Wuhan (CN)

(72) Inventor: Wanting LIU, Wuhan (CN)

(21) Appl. No.: 17/776,390

(22) PCT Filed: Apr. 22, 2022
(86) PCT No.: PCT/CN2022/088476

§ 371 Date: Nov. 14, 2024

(30) Foreign Application Priority Data
Apr. 11, 2022 (CN) 202210374915.3

(51) Int. Cl. H10K 59/80; H10K 59/12; H10K 59/38; H10K 102/00

(52) U.S. Cl. CPC H10K 59/8722; H10K 59/1201; H10K 59/38; H10K 2102/351

(57) ABSTRACT

A display screen, a manufacturing method thereof, and a display device are provided. The display screen includes: a display panel including a display portion, a bending portion, and a connection portion connected sequentially; an adhesive layer including a first portion and a second portion configured in one piece, wherein the first portion is disposed on a display surface of the display portion, and the second portion covers the bending portion; and a cover plate. A gap does not need to be reserved in an integrated adhesive layer during connecting, thereby saving this part of the space, which is beneficial to a narrowing design of a bezel of the display screen.

### FIELD OF THE DISCLOSURE

The present application relates to the field of display technology, and particularly relates to a display screen, a manufacturing method thereof, and a display device.

### DESCRIPTION OF RELATED ARTS

Technology of organic light-Emitting diode (OLED) display devices is constantly improving, and users' requirements on display devices are constantly improving. Wherein polarizer-less (POL-Less) technology is a technology that replaces polarizers of OLED products with surface photoresists. In this way, not only a thickness of display screen bodies of the display devices can be reduced, but also power consumption can be reduced by 15%-20%. Therefore, the POL-Less technology is a hot research topic in recent years.

However, in current display screens, when adhesive materials in bending regions are connected to adhesive materials in planarization regions, enough gap needs to be reserved, causing bezels of display screens cannot be narrowed.

### SUMMARY OF INVENTION

### Technical Problems

The technical problem is that in current display screens, when adhesive materials in bending regions are connected to adhesive materials in planarization regions, enough gap needs to be reserved, so that the frame of the display cannot be narrowed.

### Solution to Problem

### Technical Solutions

Embodiments of the present application provide a display screen, a manufacturing method thereof, and a display device to solve the problem that in current display screens, when adhesive materials in bending regions are connected to adhesive materials in planarization regions, enough gap needs to be reserved, so that the frame of the display cannot be narrowed.

On a first aspect, one embodiment of the present application provides a display screen, including:
a display panel including a display portion, a bending portion, and a connection portion connected sequentially, wherein the connection portion is disposed on a side facing back to a display surface of the display portion, and the bending portion is bent and is connected to the display portion and the connection portion;
an adhesive layer including a first portion and a second portion configured in one piece, the first portion is disposed on the display surface of the display portion, and the second portion covers the bending portion;
a cover plate disposed on a side of the first portion facing away the display portion.

On a second aspect, one embodiment of the present application further provides a manufacturing method of the display screen, including:
providing a display panel, wherein the display panel includes a display portion, a bending portion, and a connection portion connected sequentially,
disposing an adhesive layer having a protective film on a display surface of the display panel, wherein the adhesive layer includes a first portion and a second portion configured in one piece, the first portion is disposed corresponding to the display portion, the second portion is disposed corresponding to the bending portion, and the protective film including a first protective film disposed corresponding to the first portion and a second protective film disposed corresponding to the second portion;
removing the second protective film and performing illumination and curing on the second portion;
removing the first protective film, and disposing a cover plate on a side of the first portion facing away the display portion;
bending the display panel and the adhesive layer to make the connection part to be wound to a side of the display portion facing back to the display surface, wherein the second portion is bent in a same direction as the bending portion and covers the bending portion.

On a third aspect, one embodiment of the present application further provides a display device, including:
a display screen, which is any aforesaid display screen; and a housing configured to bear the display screen.

### Advantages of Invention

### Beneficial Effects

In the display screen, the manufacturing method thereof, and the display device of the embodiments of the present application, by using an integrated adhesive layer in the display portion and the bending portion of the display panel to replace an current solution of using different adhesive materials in the planarization region and the bending region, a gap does not need to be reserved in the integrated adhesive layer during connecting, thereby saving this part of the space, which is beneficial to a narrowing design of a bezel of the display screen.

### BRIEF DESCRIPTION OF DRAWINGS

### Description of Attached Drawings

To more clearly illustrate the technical solutions of the embodiments of the present application, the required accompanying figures for description of embodiments is described in brief as follow. Obviously, the accompanying figures described below are only part of the embodiments of the present application, from which figures those skilled in the art can derive further figures without making any inventive efforts.

In order to more completely understand the present application and beneficial effects thereof, the following is described with reference to accompanying drawings. Wherein, same reference numbers of accompanying figures denote same parts in the following description.

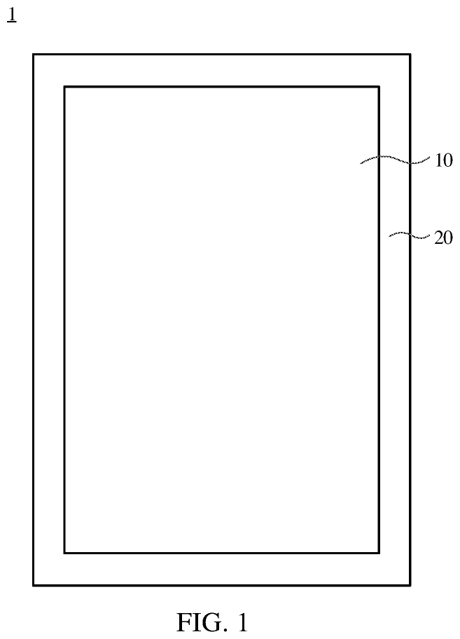

FIG. 1 is a structural schematic diagram of a display device provided by one embodiment of the present disclosure.

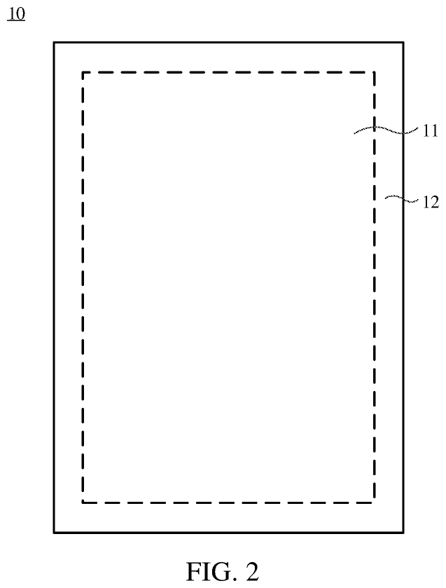

FIG. 2 is a structural schematic diagram of a display screen in the display device illustrated in FIG. 1.

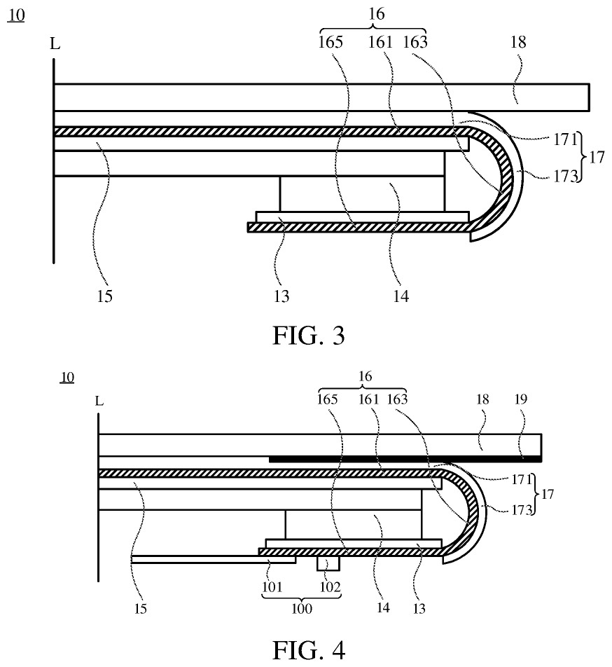

FIG. 3 is a first cross-sectional structural schematic diagram of the display screen illustrated in FIG. 2.

FIG. 4 is a second cross-sectional structural schematic diagram of the display screen illustrated in FIG. 2.

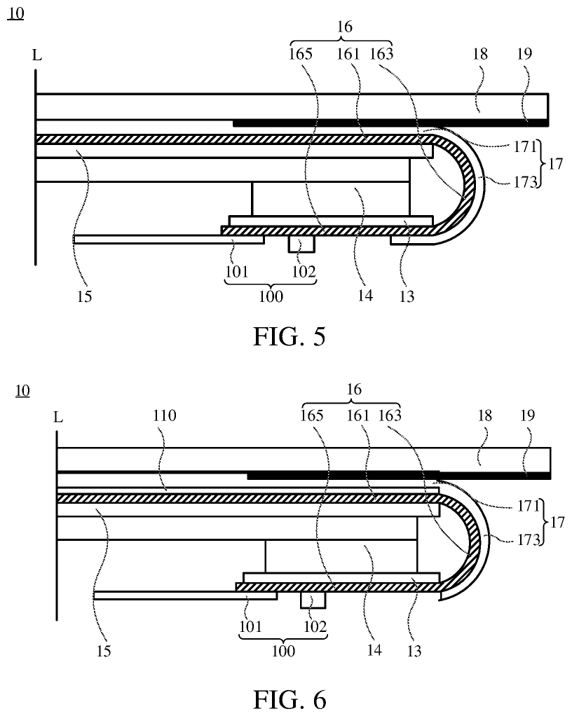

FIG. 5 is a third cross-sectional structural schematic diagram of the display screen illustrated in FIG. 2.

FIG. 6 is a fourth cross-sectional structural schematic diagram of the display screen illustrated in FIG. 2.

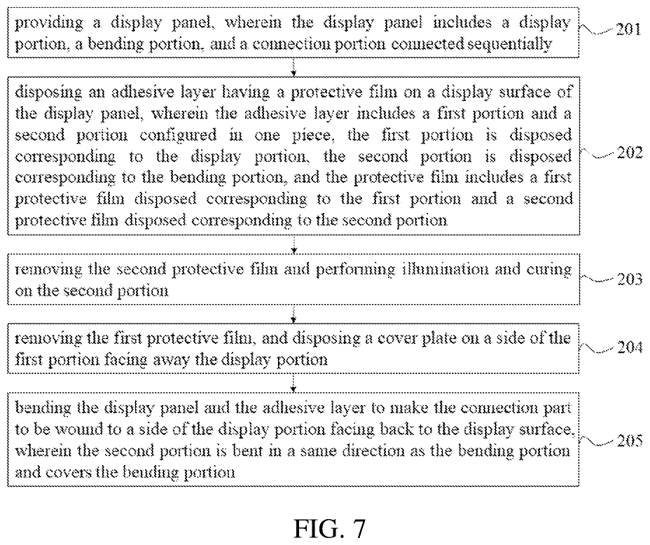

FIG. 7 is a schematic diagram of a first flowchart of a manufacturing method of the display screen provided by one embodiment of the present application.

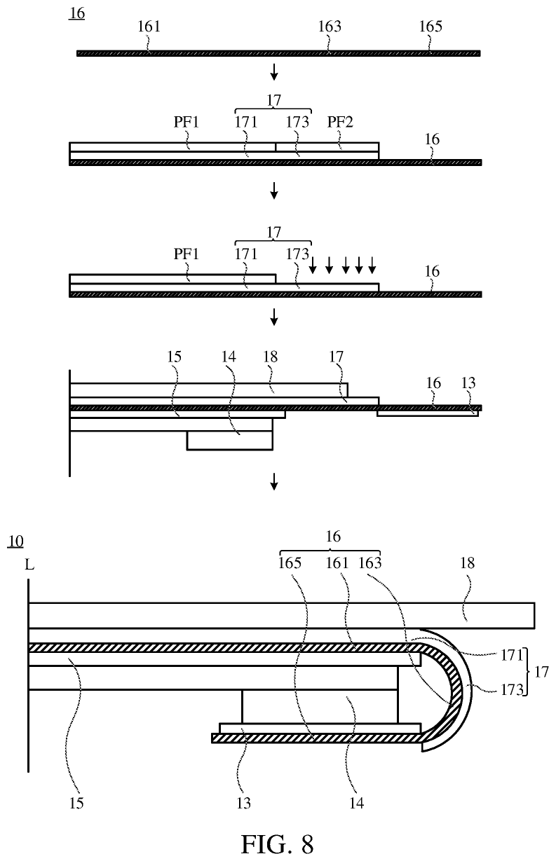

FIG. 8 is a schematic diagram of a first manufacturing process of the manufacturing method of the display screen provided by one embodiment of the present application.

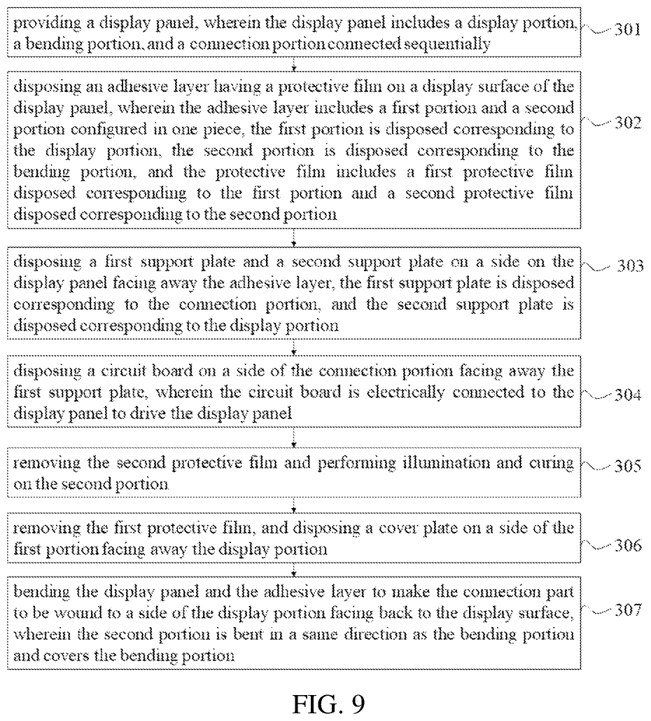

FIG. 9 is a schematic diagram of a second flowchart of the manufacturing method of the display screen provided by one embodiment of the present application.

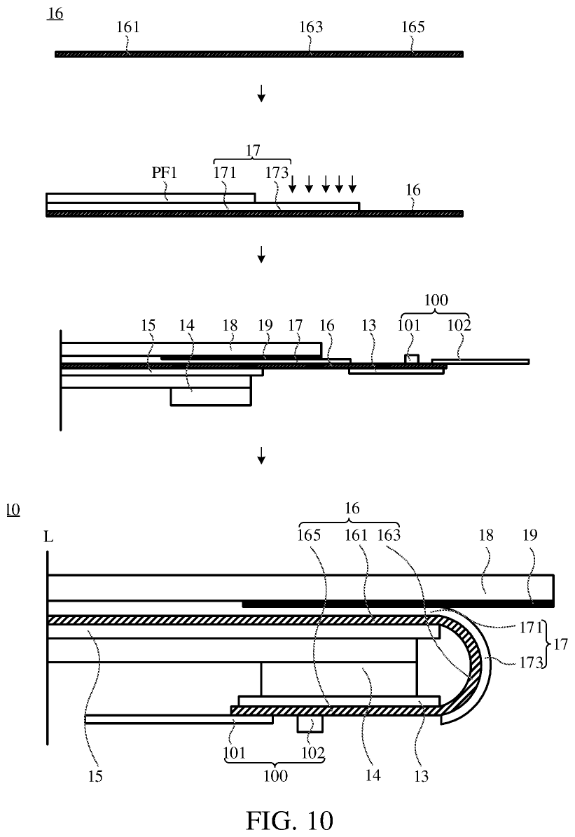

FIG. 10 is a schematic diagram of a second manufacturing process of the manufacturing method of the display screen provided by one embodiment of the present application.

### Embodiments of Invention

### DETAILED DESCRIPTION OF PREFERRED EMBODIMENTS

The technical solutions in the embodiments of the present disclosure are clearly and completely described in the following with reference to the accompanying drawings in the embodiments of the present disclosure. Obviously, the described embodiments are only part of the embodiments of the present application, but are not all embodiments of the present application. All other embodiments obtained by those skilled in the art based on the embodiments of the present disclosure without creative efforts are within the scope of the present disclosure.

In order to solve the problem that in current display screens, when adhesive materials in bending regions are connected to adhesive materials in planarization regions, enough gap needs to be reserved, causing bezels of display screens cannot be narrowed, Embodiments of the present application provide a display screen, a manufacturing method thereof, and a display device, the following is described with reference to accompanying figures.

Exemplarily, please refer to FIG. 1. FIG. 1 is a structural schematic diagram of a display device provided by one embodiment of the present disclosure. One embodiment of the present application further provides a display device 1. The display device 1 can include a display screen 10 and a housing 20. The display screen 10 is mounted in the housing 20. The housing 20 can be configured to bear the display screen 10, and a main control circuit board controlling the display screen 10, etc. can be dispose in the housing 20. For example, the display device 1 can be a mobile electronic device such as a mobile phone, a tablet, etc., and the display device 1 can also be a computer device, a television, an in-vehicle computer, or other device with a display function.

Wherein, the display screen 10 can be a device including an organic light emitting diodes (OLEDs), or a light-emitting form of components in the display screen 10 is an OLED light-emitting form. OLED belongs to a current-type organic light-emitting device, which has a light-emitting phenomenon through injection and recombination of carriers, and light-emitting intensity is proportional to injected current. Under an electric field effect, holes generated by an anode and electrons generated by a cathode can move to be respectively injected into a hole transport layer and an electron transport layer, and then migrate to a light-emitting layer. When the holes and the electrons meet at the light-emitting layer, energetic excitons are generated, thereby exciting light-emitting molecules to generate visible light at final.

Wherein, with continuous improvement of OLED display technology, users' requirements for display screens are constantly improving, and requirements for polarizer-less (POL-Less) technology is also increasingly strong. The POL-Less technology is a technology that replaces polarizers of OLED products with surface photoresists. As the polarizer is generally a multi-layer structure with a thickness achieving 106 μm, the surface photoresist is a polyimide (PI) series polymer, and a thickness of the surface photoresist is only a few microns, in this way, using the surface photoresist to replace the polarizer can not only reduce a thickness of display screen bodies, but also can reduce power consumption by 15%-20%. However, there are still many problems in Pol-Less technology that have not been overcome. For example, different types of adhesives are generally used in bending regions and planarization regions of display panels, e.g., optical clear adhesive (OCA) is commonly used in the planarization region, and ultraviolet (UV) adhesive is commonly used in the bending regions. Enough gap needs to be reserved between the UV adhesive of the bending region and an edge of the OCA in the display panel to prevent the UV adhesive to overlap with the OCA, which can cause a bezel of the display panel cannot be further narrowed. In addition, when a thickness of the UV adhesive exceeds a thickness of the OCA, an assembly interference problem can appear during connection of a cover plate.

In order to solve the aforesaid technical problem, embodiments of the present application improve structures of the display screen 10. The structure and composition of the display screen 10 and the manufacturing method of the display screen are respectively described as follow.

Exemplarily, please combine FIG. 1 and refer to FIG. 2 and FIG. 3. FIG. 2 is a structural schematic diagram of a display screen in the display device illustrated in FIG. 1. FIG. 3 is a first cross-sectional structural schematic diagram of the display screen illustrated in FIG. 2. One embodiment of the present application further provides a display screen 10. The display screen 10 can include a display region 11 and a non-display region 12. The non-display region 12 is configured to enclose the display region 11. The non-display region 12 can also be named as a bezel region. Wires, etc. can be arranged in the non-display region 12. Wherein, in the figures, L represents a boundary line between the display region and the non-display region, a left side of the boundary line L can represent the display region 11, and a right side of the boundary line L can represent the non-display region 12. The display screen 10 can include a first support plate 13, a connection element 14, a second support plate 15, a display panel 16, an adhesive layer 17, and a cover plate 18. The connection element 14 is disposed on a side of the first support plate 13. The second support plate 15 is disposed on a side of the connection element 14 facing away the first support plate 13. The display panel 16 can include a display portion 161, a bending portion 163, and a connection portion 165 connected sequentially. The connection portion 165 is disposed on a side of a display surface of the display portion 161. For example, the display portion 161 is disposed on a side of the first support plate 13 facing away the second support plate 15, the connection portion 165 is disposed on a side of the first support plate 13 facing away the second support plate 15, and the bending portion 163 is bent and is connected to the display portion 161 and the connection portion 165. The adhesive layer 17 includes a first portion 171 and a second portion 173 configured in one piece, and the first portion 171 is disposed on the display surface of the display portion 161, i.e., the first portion 171 is disposed on a side of the display portion 161 facing away the first support plate 13, and the second portion 173 covers the bending portion 163. Wherein, a thickness of the second portion 173 is equal to a thickness of the first portion 171. The cover plate 18 is disposed on a side of the first portion 171 facing away the first support plate 13 or facing away the display portion 161. Wherein, it can be understood that the second portion 173, the bending portion 163, and the connection portion 165 mentioned above are disposed in the non-display region 12. The non-display region 12 is also a region for wiring or disposing a partial structure. By using the integrated adhesive layer 17 in the display portion 161 and the bending portion 163 of the display panel 16 to replace a current solution of using different adhesive materials in a planarization region and a bending region, a gap does not need to be reserved in the integrated adhesive layer 17 during connecting, thereby saving this part of the space, which is beneficial to a narrowing design of a bezel of the display screen 10.

Wherein, exemplarily, the first support plate 13 and the second support plate 15 can both be named as backplate plates (BPs), i.e., support plates facing back to the display surface of the display panel 16. The first support plate 13 is configured to support the connection portion 165 of the display panel 16 and components disposed on the connection portion 165. The second support plate 15 is configured to support the display portion 161 of the display panel 16. An area of the second support plate 15 can be larger than an area of the first support plate 13, and an end surface the second support plate 15 toward the bending portion 163 flushes with an end surface of the first support plate 13 toward the bending portion 163. In this way, a bending shape of the bending portion 163 is allowed to be a regular arc shape. It can be understood that the first support plate 13 is disposed close to an edge of the second support plate 15.

The connection element 14 is disposed between the first support plate 13 and the second support plate 15. The connection element 14 is configured to connect the first support plate 13 and the second support plate 15. An end surface of the connection element 14 toward the bending portion 14, a terminal portion of the first support plate 13 toward the bending portion 163, and a terminal portion of the second support plate 15 toward the bending portion 263 enclose to form a groove. The end surface of the bending portion 14 toward the bending portion 163 acts a bottom wall of the groove. It can be understood that the end surface of the connection element 14 toward the bending portion and the end surface of the first support plate 13 toward the bending portion 163 are a ladder shape. Exemplarily, the connection element 14 can include a tape and a super clean foam (SCF). The adhesive tape is respectively connected to the first support plate 13 and the super clean foam. The super clean foam is connected to the first support plate 13 to the tape and the second support plate 15. It can be understood that an area of the super clean foam can be similar to the area of the second support plate 15, an area of the tape can be similar to the area of the first support plate 13, an end surface of the super clean foam toward the bending portion 163 flushes with an end surface of the tape toward the bending portion 163, and an end surface of the super clean foam facing away the bending portion 163 and an end surface of the tape facing away the bending portion 163 can be a ladder shape.

The display panel 16 can be divided into three portions: the display portion 161, the bending portion 163, and the connection portion 165. A part of the display portion 161 is located in the display region 11. Another part of the display portion 161 is located in the non-display region 12. The display portion 161 is disposed on the second support plate 15. The connection portion 165 is disposed on a side of the first support plate 13 facing back to the second support plate 15. The bending portion 163 is bent and is connected to the display portion 161 and the connection portion 165. It can be understood that the display panel 16 is bent at an edge of the display screen 10 and is wound to a back surface for connection, so as to facilitate electrical connection between the display panel 16 and other electronic devices. Because the first support plate 13 flushes with the end surface of the second support plate 15 toward the bending portion 163, a shape of the bending portion 163 can be a relatively regular arc shape.

The adhesive layer 17 can be an adhesive material of optical clear adhesive (OCA), or ultraviolet (UV) adhesive, etc. The adhesive layer is not only disposed on a location corresponding to the display portion 161 and is further applied in a region corresponding to the bending portion 163. The adhesive layer 17 includes a first portion 171 and a second portion 173 configured in one piece. The first portion 171 is disposed corresponding to the display portion 161 of the display panel 16. The second portion 173 is disposed corresponding to the bending portion 163 of the display panel 16. Exemplarily, a stickiness of the first portion 171 is greater than a stickiness of the second portion 173. It can be understood that the first portion 171 is configured to connect the display panel 16 and the cover plate 18. The second portion 173 is configured to support and protect the bending portion 163 of the display panel 16 to prevent the bending portion 163 from being exposed and intruded by water vapor, and to serve a protection function and a buffer function for bending of the bending portion 163. Therefore, the stickiness of the first portion 171 and the second portion 173 are configured to be different.

It should be noted that please combine FIG. 1 to FIG. 3 and refer to FIG. 4 and FIG. 5. FIG. 4 is a second cross-sectional structural schematic diagram of the display screen illustrated in FIG. 2. FIG. 5 is a third cross-sectional structural schematic diagram of the display screen illustrated in FIG. 2. The adhesive layer 17 does not relate to covering the connecting portion 165, but the adhesive layer 17 can extend to the connecting portion 165. For example, an end of the second portion 173 away from the first portion 171 extends to the connection portion 165 to realize protection and support at a connection position of the connection portion 165 and the bending portion 163. The reason why the adhesive layer 17 does not cover the connection portion 165 is that some electronic devices need to be disposed on the connection portion 165. For example, a circuit board 100 can further be disposed in the non-display region 12, i.e., the display screen 10 can further include the circuit board 100. The circuit board 100 is disposed on a side of the connection portion 165 facing away the display portion 161, and the circuit board 100 can be connected to the display panel 16 to drive the display panel 16. The circuit board 100 can include an integrated circuit (IC) board 101 and a flexible circuit board (FPC) 102. The integrated circuit board 101 is disposed on a side of the connection portion 165 facing away the first support plate 13. The integrated circuit board 101 can be understood as a main control board of the display panel 16 for receiving external signals for processing and sending the external signals to the display panel 16 to control display of the display panel 16. The flexible circuit board 102 is disposed on a side of the connection portion 165 facing away the first support plate 13 and is spaced apart from the integrated circuit board 101. Furthermore, an end of the flexible circuit board 102 is a hanging free end, so as to facilitate connection between the flexible circuit board 102 and other components. The flexible circuit board 102 can be understood as a connection line and is configured to connect the integrated circuit board 101 to external electronic devices.

The display screen 10 can further include ink 19. The ink 19 is disposed on a side of the cover plate 18 toward the first portion 171. The ink 19 is disposed corresponding to the bending portion 163 and the connection portion 165, and it can also be understood that the ink 19 covers the second portion 173 and a part of the first portion 171. The ink 19 is configured to cover a bent part to prevent a problem of deterioration of appearance incurred by exposing the bent part. Wherein, exemplarily, a thickness of a region of the first portion 171 corresponding to the ink 19 is less than or equal to a thickness of other region of the first portion 171. It can be understood that because a region of the first portion 171 corresponding to the ink 19 has to bear the thickness of the ink 19, the thickness of the first portion 171 is smaller in the region close to the second portion 173. Of course, when the thickness of the ink 19 is small, it can be considered that the thickness of the region of the first portion 171 corresponding to the ink 19 is equal to the thickness of other region. As the area of the region of the first portion 171 corresponding to the ink 19 is relatively small, even if the thickness of this portion is relatively thin, the cover plate 18 will not have a warpage problem when it is disposed on the adhesive layer 17, preventing the interference problem of connecting to the cover plate 18 appearing incurred by using of adhesive materials with different thicknesses in different regions.

It should be noted that please combine FIG. 1 to FIG. 5 and refer to FIG. 6. FIG. 6 is a fourth cross-sectional structural schematic diagram of the display screen illustrated in FIG. 2. The display screen 10 of one embodiment of the present application can further include a color film layer 110. The color film layer 110 is disposed between the display portion 161 and the first portion 171. Of course, in order to facilitate manufacturing processes, the color filter layer 110 can completely cover the display panel 16 (not shown in the figure). The color film layer 110 is used for color display of the display screen 10. Exemplarily, a polyimide (PI) series macromolecule polymer can be selected as a material of the color film layer 110, i.e., a photoresist material, and a thickness of the color film layer 110 can be several microns. Using the color film layer 110 to replace the polarizer can not only reduce a thickness of display screen 10, but also can reduce power consumption.

In order to describe the display screen 10 of the embodiments of the present application more clearly, a perspective of the manufacturing method of the display screen is described as follows.

Exemplarily, please combine FIG. 1 to FIG. 6 and refer to FIG. 7 and FIG. 8. FIG. 7 is a schematic diagram of a first flowchart of the manufacturing method of the display screen provided by one embodiment of the present application. FIG. 8 is a schematic diagram of a first manufacturing process of the manufacturing method of the display screen provided by one embodiment of the present application. The manufacturing method of the display screen includes:

201: providing a display panel, wherein the display panel includes a display portion, a bending portion, and a connection portion connected sequentially.

The display panel 16 can be composed of a multi-layer structure. For example, the display panel 16 can include an array substrate, a light-emitting layer, and an encapsulation layer. A plurality of thin film transistors can be disposed on the array substrate. The light-emitting layer can include structures such as an organic light-emitting semiconductor, a cathode, an anode, an electron transport layer, etc.

The completely manufactured display panel 16 can be divided into three portions of the display portion 161, the bending portion 163, and the connection portion 165. The display portion 161 can be configured to connect to the cover plate. The connection portion 165 is configured to connect to the circuit board. The bending portion 163 is configured to make the display portion 161 and the connection portion 165 disposed on different planes in bend connection.

202: disposing an adhesive layer having a protective film on a display surface of the display panel, wherein the adhesive layer includes a first portion and a second portion configured in one piece, the first portion is disposed corresponding to the display portion, the second portion is disposed corresponding to the bending portion, and the protective film includes a first protective film disposed corresponding to the first portion and a second protective film disposed corresponding to the second portion.

When the adhesive layer 17 is supplied, protective films are disposed on two opposite lateral sides of the adhesive layer 17. In order to facilitate processing or subsequent production, the adhesive layer 17 is divided into a first portion 171 and a second portion 173 configured in one piece. When the adhesive layer 17 needs to be attached to the display panel 16, the protective film on one side of the adhesive layer 17 is removed. The protective film on the other side of the remaining adhesive layer 17 can be configured as a first protective film PF1 and a second protective film PF2 which are segmented. The first protective film PF1 is disposed corresponding to the first portion 171. The second portion PF2 is dispose corresponding to the second portion 173. It should be noted that when the adhesive layer 17 is supplied, both sides of the adhesive layer 17 have stickiness for preventing foreign matter from sticking. Therefore, the protective film needs to be disposed.

The adhesive layer 17 can be disposed to correspond to different parts of the display panel 16. For example, the first portion 171 can be disposed corresponding to the display portion 161, the first portion 171 is configured to connect to the display portion 161 and the cover plate 18 of the display panel 16, the second portion 173 can be disposed corresponding to the bending portion 163, and the second portion 173 is configured to support and protect the bending portion 163. Therefore, the stickiness of the first portion 171 can be configured to be greater than the stickiness of the second portion 173. It should be noted that the connecting portion 165 is not connected to the adhesive layer 17, and the connecting portion 165 is configured to connect to other electronic devices.

When the adhesive layer 17 is disposed, the first part 171 having the first protective film PF1 is disposed corresponding to the display portion 161, and the second portion 173 having the second protective film PF2 is disposed corresponding to the bending portion 163. As the second portion 173 needs to be cured then used, and the first part 171 is used as adhesive, the first portion 171 and the second portion 173 are protected by the first protective film PF1 and the second protective film PF2 respectively to prevent influence on a state of the first portion 171 when the second portion 173 is cured by light.

203: removing the second protective film and performing illumination and curing on the second portion.

204: removing the first protective film, and disposing a cover plate on a side of the first portion facing away the display portion.

About the steps 203 and 204:
the second portion 173 is configured to support and protect the bending portion 163. Therefore, it needs to be cured until it has no stickiness. Furthermore, the first portion 171 is configured to connect to the display panel 16 and the cover plate 18. Therefore, the first part 171 needs to be cured after being connected to the cover plate 18 to make connection be firm. That is, the stickiness of the first portion 171 is greater than the stickiness of the second portion 173. In order to prevent influence of the curing of the second portion 173 on the first portion 171, the adhesive layer 17 is cured in stages. That is, the second protective film PF2 is removed first, and then illumination and curing are performed on the second portion 173. After that, the first protective film PF1 is removed, and then the cover plate 18 is disposed on the side of the first portion 171 facing away the display portion 161. Light curing is performed from a side of the cover plate 18 facing away the first portion 171 to make the cover plate 18 and the first part 171 be firmly connected.

The method of curing the adhesive layer in stages can make the first portion 171 to fulfill the function of connecting the display panel 16 and the cover plate 18, while allows the second part 173 to fulfill the function of supporting and protecting the bending portion 163.

Wherein, when the cover plate 18 is provided, the ink 19 can be dispose on a mounting side of the cover plate 18, and the ink 19 is configured to block the structure of the bending region to improve an appearance of the display screen 10. Because the ink 19 contacts with the first portion 171 of the adhesive layer 17, the thickness of the region of the first portion 171 corresponding to the ink 19 can be less than or equal to the thickness of other region of the first portion 171.

205: bending the display panel and the adhesive layer to make the connection part to be wound to a side of the display portion facing back to the display surface, wherein the second portion is bent in a same direction as the bending portion and covers the bending portion.

In order to reduce a bezel of the display screen 10, i.e., a width of the non-display region of the display screen 10, the circuit board is generally disposed on the side of the display panel 16 facing back to the display surface. Regarding to organic light emitting diode (OLED) screens, which can be flexible screens. Therefore, a part of the display panel 16 can be bent, i.e., the bending portion 163 bent and connected to the display portion 161 and the connection portion 165 is obtained. At this time, the second portion 173 of the adhesive layer 17 and the bending portion 163 are bent simultaneously, the second portion 173 of the adhesive 17 covers the bending portion 163 to perform support and protection on the bending portion 163. As a result, a structural arrangement scheme in the non-display region 12 of the display screen 10 is obtained.

By curing the adhesive layer 17 in stages, the gap between the adhesive layer 17 and the bending region can be removed, the bezel of the display screen 10 is further narrowed, and the problem of assembly interference of the cover plate 18 incurred by the thickness of the conventional UV adhesive exceeding the thickness of the adhesive layer 17 is prevented.

It should be noted that, the aforesaid steps are only one manufacturing method of the display screen 10. In actual production processes, the order of the steps can be changed as needed.

Wherein, the display screen 10 further includes the first support plate 13, the second support plate 15, and the circuit board 100. Exemplarily, please combine FIG. 1 to FIG. 8 and refer to FIG. 9 and FIG. 10. FIG. 9 is a schematic diagram of a second flowchart of the manufacturing method of the display screen provided by one embodiment of the present application. FIG. 10 is a schematic diagram of a second manufacturing process of the manufacturing method of the display screen provided by one embodiment of the present application. One embodiment of the present application further provides the manufacturing method of the display screen, including:

301: providing a display panel, wherein the display panel includes a display portion, a bending portion, and a connection portion connected sequentially.

302: disposing an adhesive layer having a protective film on a display surface of the display panel, wherein the adhesive layer includes a first portion and a second portion configured in one piece, the first portion is disposed corresponding to the display portion, the second portion is disposed corresponding to the bending portion, and the protective film includes a first protective film disposed corresponding to the first portion and a second protective film disposed corresponding to the second portion.

The steps 301 and 302 can refer to the descriptions of steps 201 and 202, unnecessary details will not be given herein again.

303: disposing a first support plate and a second support plate on a side on the display panel facing away the adhesive layer, the first support plate is disposed corresponding to the connection portion, and the second support plate is disposed corresponding to the display portion.

The first support plate 13 and the second support plate 15 can both be named as backplate plates (BPs), i.e., support plates facing back to the display surface of the display panel 16. The first support plate 13 is configured to support the connection portion 165 of the display panel 16 and components disposed on the connection portion 165. The second support plate 15 is configured to support the display portion 161 of the display panel 16. An area of the second support plate 15 can be larger than an area of the first support plate 13, and an end surface the second support plate 15 toward the bending portion 163 flushes with an end surface of the first support plate 13 toward the bending portion 163. In this way, a bending shape of the bending portion 163 is allowed to be a regular arc shape. It can be understood that the first support plate 13 is disposed close to an edge of the second support plate 15.

A connection element 14 can be further disposed between the first support plate 13 and the second support plate 15. The connection element 14 is configured to connect the first support plate 13 and the second support plate 15.

304: disposing a circuit board on a side of the connection portion facing away the first support plate, wherein the circuit board is electrically connected to the display panel to drive the display panel.

The circuit board 100 is disposed on a side of the connection portion 165 facing away the display portion 161, and the circuit board 100 can be connected to the display panel 16 to drive the display panel 16. The circuit board 100 can include an integrated circuit (IC) board 101 and a flexible circuit board (FPC) 102. The integrated circuit board 101 is disposed on a side of the connection portion 165 facing away the first support plate 13. The integrated circuit board 101 can be understood as a main control board of the display panel 16 for receiving external signals for processing and sending the external signals to the display panel 16 to control display of the display panel 16. The flexible circuit board 102 is disposed on a side of the connection portion 165 facing away the first support plate 13 and is spaced apart from the integrated circuit board 101. Furthermore, an end of the flexible circuit board 102 is a hanging free end, so as to facilitate connection between the flexible circuit board 102 and other components. The flexible circuit board 102 can be understood as a connection line and is configured to connect the integrated circuit board 101 to connect to external electronic devices.

305: removing the second protective film and performing illumination and curing on the second portion.

306: removing the first protective film, and disposing a cover plate on a side of the first portion facing away the display portion.

307: bending the display panel and the adhesive layer to make the connection part to be wound to a side of the display portion facing back to the display surface, wherein the second portion is bent in a same direction as the bending portion and covers the bending portion.

The steps 305 and 307 can refer to the descriptions of steps 203 and 205, unnecessary details will not be given herein again.

Wherein, the arrangement of the color filter layer 110 can be performed before the adhesive layer 17 disposed on the display panel 16, and unnecessary details will not be given herein again.

In the display screen 10, the manufacturing method thereof, and the display device 1 of the embodiments of the present application, by using the integrated adhesive layer 17 in the display portion 161 and the bending portion 163 of the display panel 16 to replace an current solution of using different adhesive materials in a planarization region and a bending region, a gap does not need to be reserved in the integrated adhesive layer 17 during connecting, thereby saving this part of the space, which is beneficial to a narrowing design of a bezel of the display screen 10.

In the above embodiments, the description of each embodiment has its emphasis, and for some embodiments that may not be detailed, reference may be made to the relevant description of other embodiments.

In the description of the present application, the terms “first” and “second” are used for descriptive purposes only and are not to be understood as indicating or implying relative importance or implicitly indicating the number of the indicated technical characteristics. Therefore, the characteristics defined by “first” or “second” may include one or more of the described characteristics either explicitly or implicitly.

The display screen, the manufacturing method thereof, and the display device provided by the embodiments of the present application are described in detail. This article uses specific cases for describing the principles and the embodiments of the present application, and the description of the embodiments mentioned above is only for helping to understand the method and the core idea of the present application. Meanwhile, for those skilled in the art, will have various changes in specific embodiments and application scopes according to the idea of the present application. In summary, the content of the specification should not be understood as limit to the present application.

What is claimed is:

1. A display screen, comprising:
a display panel comprising a display portion, a bending portion, and a connection portion connected sequentially, wherein the connection portion is disposed on a side facing back to a display surface of the display portion, the bending portion is bent and is connected to the display portion and the connection portion;
an adhesive layer comprising a first portion and a second portion configured in one piece, the first portion is disposed on the display surface of the display portion, and the second portion covers the bending portion; and
a cover plate disposed on a side of the first portion facing away the display portion.

2. The display screen as claimed in claim 1, wherein a stickiness of the first portion is greater than a stickiness of the second portion.

3. The display screen as claimed in claim 1, wherein the display screen comprises:
a first support plate attached to a side of the connection portion toward the display portion; and
a second support plate attached to a side of the display portion toward the connection portion, wherein an end surface the second support plate toward the bending portion flushes with an end surface of the first support plate toward the bending portion.

4. The display screen as claimed in claim 3, wherein the display screen comprises:
an ink disposed on a side of the cover plate toward the first portion, wherein the ink is disposed corresponding to the bending portion and the connection portion.

5. The display screen as claimed in claim 4, wherein a thickness of a region of the first portion corresponding to the ink is less than or equal to a thickness of other region of the first portion.

6. The display screen as claimed in claim 1, wherein the display screen comprises:
a circuit board disposed on a side of the connection portion facing away the display portion, wherein the circuit board is electrically connected to the display panel to drive the display panel.

7. The display screen as claimed in claim 1, wherein the display screen comprises:
a color film layer disposed between the display portion and the first portion.

8. The display screen as claimed in claim 1, wherein an end of the second portion away from the first portion extends to the connection portion.

9. The display screen as claimed in claim 3, wherein the display screen comprises:
a connection element, wherein the connection element is disposed between the first support plate and the second support plate.

10. The display screen as claimed in claim 9, wherein the connection element comprises:
a tape disposed on a side of the first support plate toward the second support plate;
a foam disposed on a side of the second support plate toward the first support plate and connected to the tape.

11. A manufacturing method of a display screen, comprising:
providing a display panel, wherein the display panel comprises a display portion, a bending portion, and a connection portion connected sequentially,
disposing an adhesive layer having a protective film on a display surface of the display panel, wherein the adhesive layer includes a first portion and a second portion configured in one piece,
the first portion is disposed corresponding to the display portion,
the second portion is disposed corresponding to the bending portion, and the protective film comprising a first protective film disposed corresponding to the first portion and a second protective film disposed corresponding to the second portion;
removing the second protective film and performing illumination and curing on the second portion;
removing the first protective film, and disposing a cover plate on a side of the first portion facing away the display portion;
bending the display panel and the adhesive layer to make the connection part to be wound to a side of the display portion facing back to the display surface,
wherein the second portion is bent in a same direction as the bending portion and covers the bending portion.

12. The manufacturing method as claimed in claim 11, wherein before removing the second protective film and performing the illumination and curing on the second portion, the manufacturing method comprises:
disposing a first support plate and a second support plate on a side on the display panel facing away the adhesive layer, the first support plate is disposed corresponding to the connection portion, and the second support plate is disposed corresponding to the display portion.

13. A display device, comprising:
a display screen comprising:
a display panel comprising a display portion, a bending portion, and a connection portion connected sequentially, wherein the connection portion is disposed on a side facing back to a display surface of the display portion, the bending portion is bent and is connected to the display portion and the connection portion;
an adhesive layer comprising a first portion and a second portion configured in one piece, the first portion is disposed on the display surface of the display portion, and the second portion covers the bending portion;
a cover plate disposed on a side of the first portion facing away the display portion; and
a housing configured to bear the display screen.

14. The display device as claimed in claim 13, wherein a stickiness of the first portion is greater than a stickiness of the second portion.

15. The display device as claimed in claim 13, wherein the display screen comprises:
a first support plate attached to a side of the connection portion toward the display portion; and
a second support plate attached to a side of the display portion toward the connection portion, wherein an end surface the second support plate toward the bending portion flushes with an end surface of the first support plate toward the bending portion.

16. The display device as claimed in claim 15, wherein the display screen comprises:
an ink disposed on a side of the cover plate toward the first portion, wherein the ink is disposed corresponding to the bending portion and the connection portion.

17. The display device as claimed in claim 16, wherein a thickness of a region of the first portion corresponding to the ink is less than or equal to a thickness of other region of the first portion.

18. The display device as claimed in claim 13, wherein the display screen comprises:
a circuit board disposed on a side of the connection portion facing away the display portion, wherein the circuit board is electrically connected to the display panel to drive the display panel.

19. The display device as claimed in claim 13, wherein the display device comprises: the display screen comprises:
a color film layer disposed between the display portion and the first portion.

20. The display screen as claimed in claim 15, wherein the display screen comprises:
a connection element, wherein the connection element is disposed between the first support plate and the second support plate.
